(19) United States
(12) Patent Application Publication
(10) Pub. No.: US 2015/0233974 A1
(43) Pub. Date: Aug. 20, 2015

(54) METER OR DISPLAY DEVICE FOR CALCULATION AND DISPLAY OF ARC FLASH INCIDENT ENERGY

(71) Applicant: EATON CORPORATION, Cleveland, OH (US)

(72) Inventors: JAMES L. LAGREE, ROBINSON TOWNSHIP, PA (US); JOEL E. BENZING, ARDEN, NC (US); CHRISTOPHER A. ROGAN, BRIGHTWATERS, NY (US); RUFUS L. BARNES, CRANBERRY TOWNSHIP, PA (US); ANTHONY T. RICCIUTI, BETHEL PARK, PA (US)

(73) Assignee: EATON CORPORATION, CLEVELAND, OH (US)

(21) Appl. No.: 14/182,522

(22) Filed: Feb. 18, 2014

(51) Int. Cl. G01R 13/02; G01R 21/133

(52) U.S. Cl. CPC G01R 13/02; G01R 21/133

(57) ABSTRACT

A meter or display device for at least one power circuit zone. The device includes a processor having a plurality of dynamic inputs, a routine and an output. The routine is structured to input the dynamic inputs, calculate incident energy of one power circuit zone of the at least one power circuit zone, and output the output. A display is structured to display at least the calculated incident energy from the output of the processor.

### BACKGROUND

1. Field

The disclosed concept pertains generally to electrical distribution apparatus, such as switchgear and panelboards, and, more particularly, to devices that indicate arc flash incident energy of such electrical distribution apparatus.

2. Background Information

The National Fire Protection Association (NFPA) standard NFPA 70E-Standard for Electrical Safety in the Workplace (2009) defines Arc Flash Hazard as being a dangerous condition associated with the possible release of energy caused by an electric arc. The standard also defines Arc Flash Hazard Analysis as being a study investigating a worker's potential exposure to arc flash energy, conducted for the purpose of injury prevention and the determination of safe work practices, arc flash protection boundary, and the appropriate levels of Personal Protective Equipment (PPE) that a worker would have to wear to protect against the level of incident energy that is released if there should be an incident creating an arc flash.

For arc flash protection, NFPA 70 110.16 and NFPA 70E 400.11 require that switchboards, panelboards, industrial control panels, meter socket enclosures, and motor control centers that are in other than dwelling occupancies and are likely to require examination, adjustment, servicing or maintenance while energized be field marked to warn qualified persons of potential electric arc flash hazards. The marking shall be located so as to be clearly visible to qualified persons before examination, adjustment, servicing or maintenance of the equipment.

A known process of evaluating an available fault current, an incident energy and a PPE level (e.g., without limitation, gloves; flame retardant garments) for a particular power system is for an engineer to perform theoretical calculations using power system parameters. A known approach to analyze the incident arc flash of electrical distribution equipment involves an engineer reviewing the equipment and a one line diagram of the corresponding power distribution system and using IEEE 1584 standard calculations and the NFPA 70E standard to assign a value of arc flash incident energy for particular pieces of distribution equipment listed in the one line diagram. Then, based on the calculations, a printed label is affixed to the power system equipment stating the manually calculated available fault current, the manually calculated incident energy and the manually calculated PPE level. There is, however, no known way to verify the correctness of this static information. There is further the risk that if the power system is modified, the manually calculated available fault current, the manually calculated incident energy and the manually calculated PPE level will change, but the printed label will not be timely changed, if at all.

U.S. Pat. No. 8,493,012 discloses an electrical switching apparatus, such as a medium voltage motor starter, that determines fault current available at a medium voltage motor and displays that available fault current along with a number of incident energy at medium voltage motor starter, and PPE level required by operators or maintenance personnel assigned to operate or maintain the medium voltage motor starter.

There are, however, many factors in the arc flash incident energy value that change when parameters in the system change.

There is room for improvement in devices that calculate and display arc flash incident energy.

### SUMMARY

These needs and others are met by embodiments of the disclosed concept in which incident energy of a power circuit zone is calculated employing dynamic inputs and the calculated incident energy is displayed.

In accordance with aspects of the disclosed concept, a meter or display device for at least one power circuit zone comprises: a processor including a plurality of dynamic inputs, a routine and an output, the routine being structured to input the dynamic inputs, calculate incident energy of one power circuit zone of the at least one power circuit zone, and output the output; and a display structured to display at least the calculated incident energy from the output of the processor.

### BRIEF DESCRIPTION OF THE DRAWINGS

A full understanding of the disclosed concept can be gained from the following description of the preferred embodiments when read in conjunction with the accompanying drawings in which:

FIG. 1 is a block diagram of switchgear including a meter or display device to calculate and display arc flash incident energy for the switchgear in accordance with embodiments of the disclosed concept.

FIG. 2 is a block diagram of a system including a meter or display device to display a one line diagram of an electrical distribution system and to calculate and display arc flash incident energy at plural different locations on the diagram for the system in accordance with another embodiment of the disclosed concept.

FIG. 3 is a representation of the one line diagram of FIG. 2 displaying plural calculated arc flash incident energy values from a plurality of meter or display devices distributed throughout the electrical distribution system.

FIGS. 4A-4D are flowcharts of routines executed by the meter or display device of FIG. 1.

FIG. 5 is a representation of a portion of a one line diagram similar to a portion of the one line diagram of FIG. 2 except showing a circuit breaker in an Arc Reduction Maintenance System (ARMS) mode and the display showing a relatively lower value of potential incident energy and an area of the electrical distribution system being protected.

FIG. 6 is a representation of a portion of a one line diagram similar to a portion of the one line diagram of FIG. 2 except showing an area of the electrical distribution system that has Zone Selective Interlocking (ZSI) enabled and the displays are showing relatively lower values of potential incident energy and the area of the system being protected.

FIG. 7 is a representation of a portion of a one line diagram similar to a portion of the one line diagram of FIG. 2 except showing an area of the electrical distribution system that has a circuit breaker that is opened and the display is showing a relatively lower value of potential incident energy and the area of the system being protected.

FIG. 8 is a representation of a one line diagram similar to the one line diagram of FIG. 2 except showing a generator that is turned on and a corresponding circuit breaker and tie circuit breaker are closed and paralleled with a utility feed and the displays are showing relatively higher values of potential incident energy throughout the electrical distribution system because of the added contribution of energy by the generator.

FIG. 9 is an isometric view of switchgear including a meter or display device having a personnel distance sensor in accordance with another embodiment of the disclosed concept.

FIG. 10 is an isometric view of switchgear including a plurality of doors and door sensors for the doors in accordance with another embodiment of the disclosed concept.

FIG. 11 is a block diagram in schematic form of the meter or display device of FIG. 1.

### DESCRIPTION OF THE PREFERRED EMBODIMENTS

As employed herein, the term “number” shall mean one or an integer greater than one (i.e., a plurality).

As employed herein, the term “processor” shall mean a programmable analog and/or digital device that can store, retrieve, and process data; a computer; a workstation; a personal computer; a controller; a digital signal processor; a microprocessor; a microcontroller; a microcomputer; a central processing unit; a mainframe computer; a mini-computer; a server; a networked processor; or any suitable processing device or apparatus.

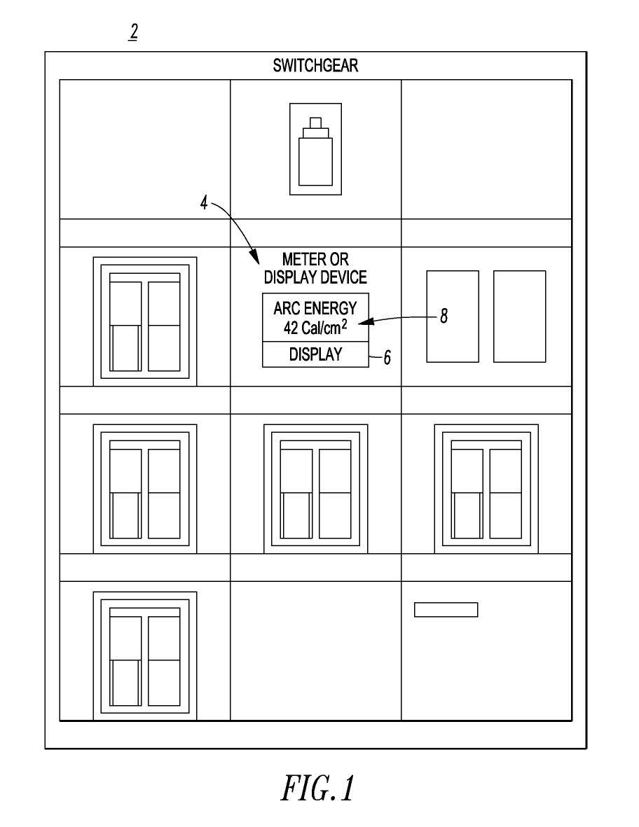

Referring to FIG. 1, switchgear 2 is shown including a meter or display device 4 to calculate and display arc flash incident energy for the switchgear 2. A display 6 displays a dynamic value 8 representing the calculated incident energy.

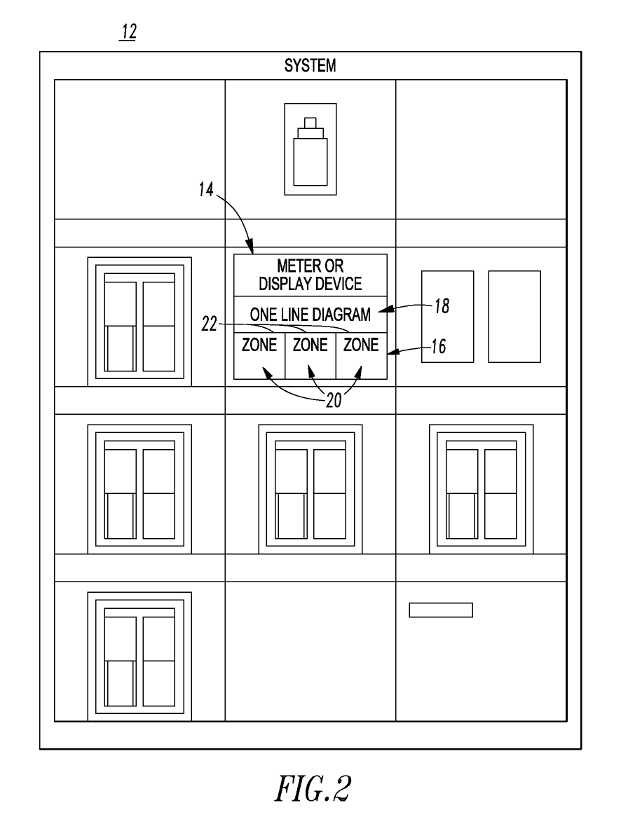

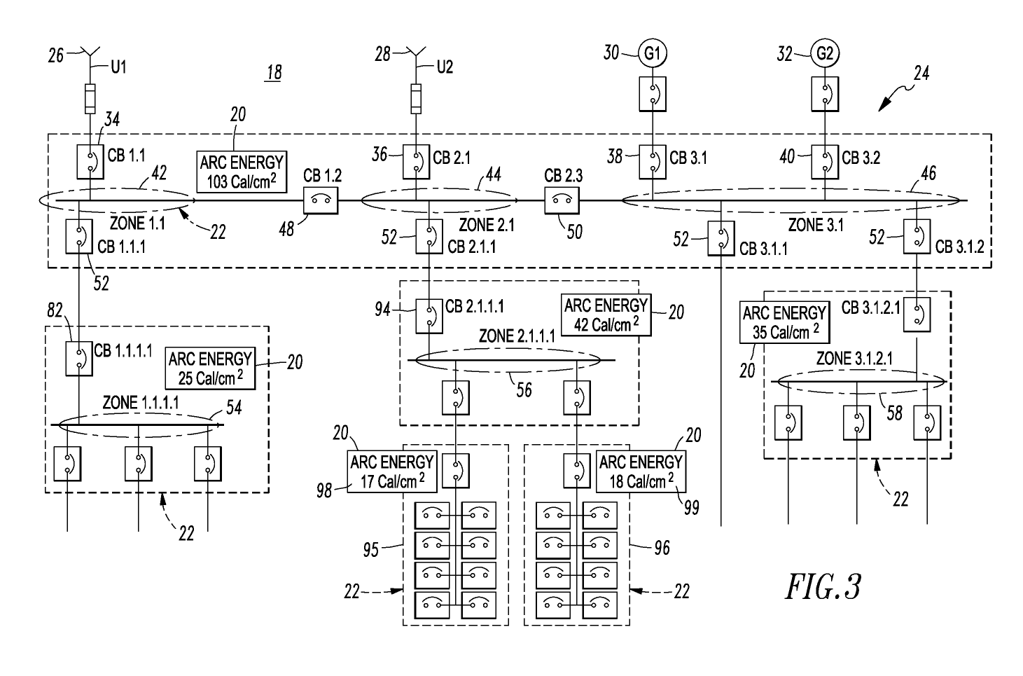

FIG. 2 shows a system 12 including another meter or display device 14, which may be the same as or similar to the device 4 of FIG. 1. The device 14 includes a display 16 that displays a one line diagram 18 (best shown in FIG. 3) of an electrical distribution system. The device 14 calculates and displays plural different dynamic arc flash incident energy values 20 at a number of different locations 22 (e.g., zones) of the system 12. The device 14 can advantageously be located at any suitable location in a building or system. For example and without limitation, displaying the one line diagram 18 of FIG. 2 may be a mode of operation of the device 4 of FIG. 1 (which can also display the dynamic value 8 for a particular location). The one line diagram 18 may display a representation of a plurality of different power circuit zones as the number of different locations 22 of the system 12.

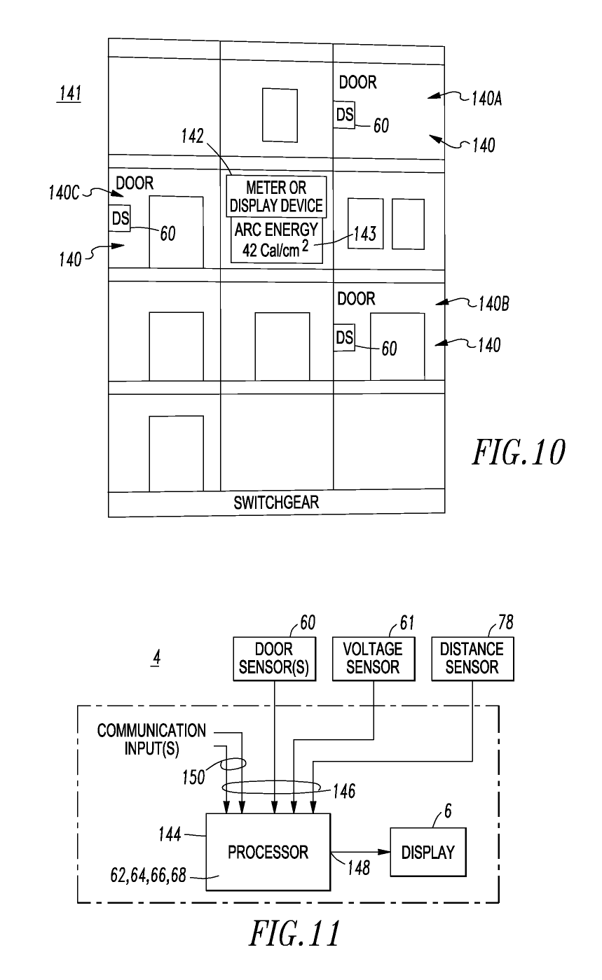

FIG. 3 shows a representation of the one line diagram 18 of FIG. 2 displaying the different dynamic arc flash incident energy values 20 at the number of different locations 22 of the system 12. For example, each of the different energy values 20 may be calculated and displayed by the device 14 of FIG. 2, or each of the different energy values 20 may be calculated by a device similar to the device 4 of FIG. 1 and communicated (e.g., employing a communication bus or network to the communication input 150 of FIG. 11) to the device 14 of FIG. 2 for reception and display. Each such device 4,14 may be distributed throughout the system 12, with one device at each of the number of different locations 22 of the system 12. Each of the different energy values 20 is a calculated incident energy for a corresponding one of the different locations 22 (e.g., different power circuit zones).

The devices 4,14 of FIGS. 1 and 2 are preferably configured for bolted fault current (I_{bf}) (e.g., maximum short circuit current) for each of the different locations 22 (e.g., different power circuit zones) of a system, such as 12. For example and without limitation, in the system 24 of FIG. 3, there are two utility sources 26 (U1), 28 (U2), and two generators 30 (G1), 32 (G2), each of which has a corresponding circuit breaker 34,36,38,40. This forms three example zones 42 (zone 1.1), 44 (zone 2.1) and 46 (zone 3.1) separated by two example tie circuit breakers 48,50. A plurality of branch circuit breakers 52 are electrically connected downstream of upper zones 42,44,46, and three example downstream zones 54 (zone 1.1.1.1), 56 (zone 2.1.1.1) and 58 (zone 3.1.2.1) are formed.

For example and without limitation, for zone 42 (zone 1.1), the bolted fault current (I_{bf}) is entered for various possible configurations of the utility sources 26,28 and the generators 30,32 (not all of which may be listed in this non-limiting example):

I_{bf} (U1 only)=60 kA (e.g., calculated from the short circuit capability of the utility source U1 and the impedance from that source to the zone 42),

I_{bf} (U2 only)=40 kA,

I_{bf} (U1+U2)=100 kA (e.g., calculated from the short circuit capability of both sources U1,U2 to the zone 42),

I_{bf} (G1 only)=10 kA,

I_{bf} (G2 only)=10 kA,

I_{bf} (U1+U2+G1)=110 kA,

I_{bf} (U1+U2+G2)=110 kA, and

I_{bf} (U1+U2+G1+G2)=120 kA.

For example and without limitation, for downstream zone 54 (zone 1.1.1.1), the bolted fault current (I_{bf}) is entered for various possible configurations of the utility sources 26,28 and the generators 30,32 (not all of which may be listed in this non-limiting example):

I_{bf} (U1 only)=42 kA,

I_{bf} (U2 only)=43 kA,

I_{bf} (U1+U2)=85 kA,

I_{bf} (G1 only)=5 kA,

I_{bf} (G2 only)=5 kA,

I_{bf} (U1+U2+G1)=90 kA, and

I_{bf} (U1+U2+G1+G2)=95 kA.

The arcing current (Iₐ) at each location (e.g., zone) is calculated from Equation 1:

log Iₐ=K+0.662 log I_{bf}+0.0966V+0.000526G+0.5588V log I_{bf}−0.00304G log I_{bf} (Eq. 1)

wherein:

Iₐ is arcing current (kA);

K is −0.153 for open enclosure configurations (e.g., open air equipment or a worker working on a cable), or is −0.097 for box configurations (e.g., switchgear; load center; panelboard);

I_{bf} is bolted fault current (kA);

V is measured system voltage (kV) from a voltage sensor 61 (FIG. 11 for the location); and

G is a gap between conductors and is 32 mm for switchgear and 25 mm for a panelboard and is predetermined for each location.

The normalized incident energy (Ea) is calculated from Equation 2:

log Eₙ=K₁+K₂+1.081 log Iₐ+0.0011G (Eq. 2)

wherein:

K₁ is −0.792 for open enclosure configurations, or is −0.555 for box enclosure configurations; and

K₂ is 0 for ungrounded and high resistance grounded systems, or is −0.113 for grounded systems and is predetermined for each location.

The final incident energy (E) (J/cm²) at each location is calculated from Equation 3:

E=4.184C_{f}Eₙ(t/0.2)(610^{X}/D^{X}) (Eq. 3)

wherein:

C_{f} is 1.0 for voltages above 1 kV, and 1.5 for voltages below 1 kV;

X=distance exponent determined by the type of switchgear and system voltage;

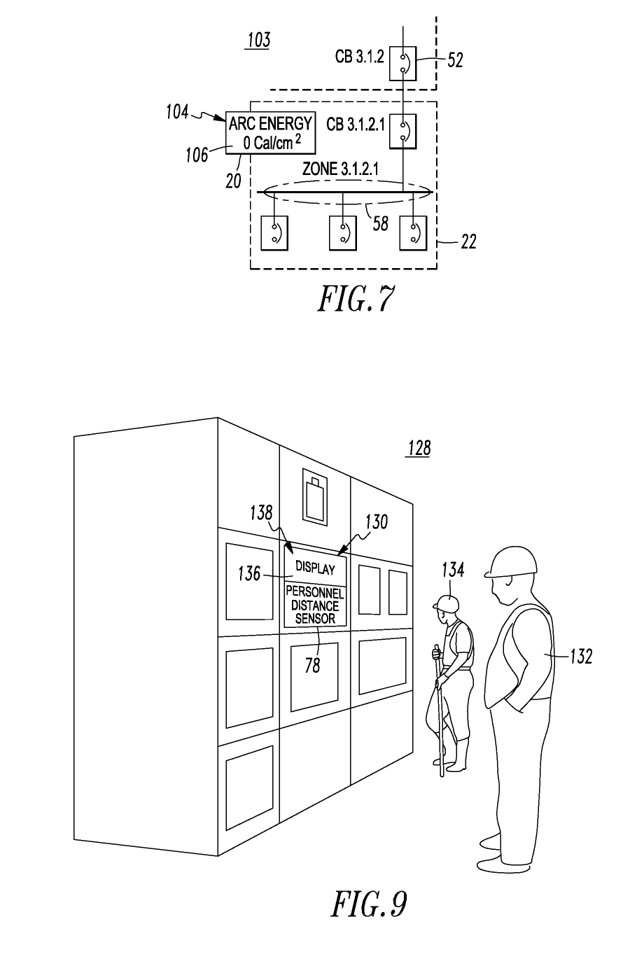

t is the arcing interruption time (seconds) of a circuit interrupter (e.g., circuit breaker 52 of FIG. 3) feeding each location as selected from three possible times:
tₘₐₓ=maximum fault interruption time,
t_{ZSI}=a smaller interruption time whenever Zone Selective Interlocking (ZSI) is enabled for the location, and
t_{ARMS}=the fastest interruption time whenever Arc Reduction Maintenance System (ARMS) is enabled for the location; and D is sensed distance (mm) from a possible arcing point in the location to a person using a distance sensor 78 (FIG. 9).

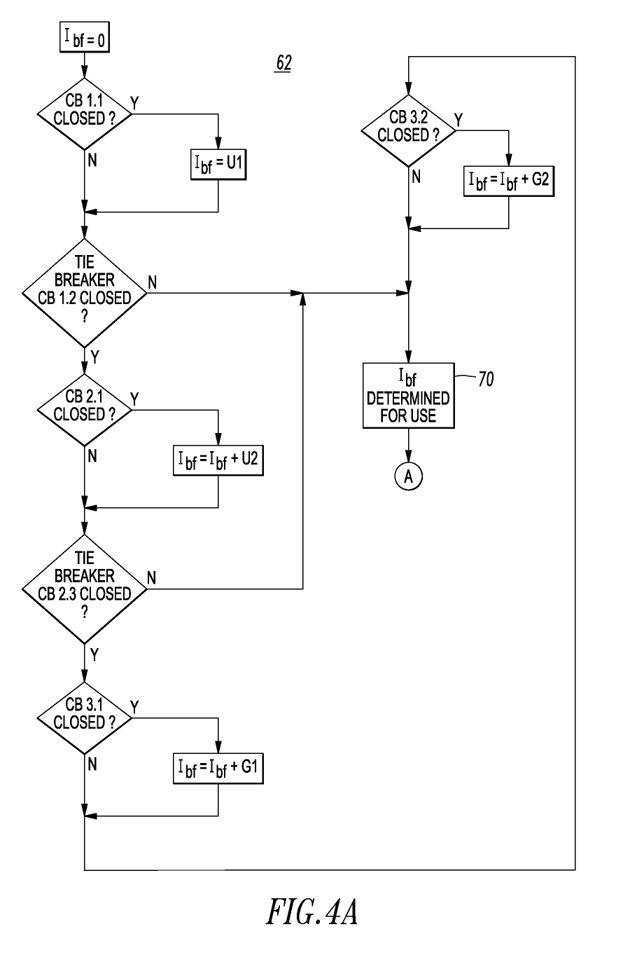

FIGS. 4A-4D show example routines 62,64,66,68 executed by the meter or display device 4 of FIG. 1. These example routines correspond to the example zone 42 (zone 1.1) of FIG. 3. Persons of ordinary skill in the art will appreciate that other suitable routines can be provided for any of the other example zones 44,46,54,56,58 of FIG. 3.

Referring to FIG. 4A, the example routine 62 determines the bolted fault current (I_{bf}) at 70 based upon the open or closed states of various circuit breakers 34,36,38,40,48,50 operatively associated with the example zone 42 (zone 1.1) of FIG. 3. Communication of these open or closed circuit breaker states and communication of the availability of the various power sources 26,28,30,32 is discussed, below, in connection with FIG. 11. The routine 62 determines the bolted fault current for the different power sources (e.g., U1,U2,G1,G2 of FIG. 3) that are available (e.g., based, in part, upon the open or closed states of the various circuit breakers operatively associated with the example zone 42 (zone 1.1)).

As shown in FIG. 4B, the example routine 64 determines the arcing current (Iₐ) at 72 employing Equation 1 based upon the switchgear configuration, whether the corresponding zone includes switchgear or a panelboard, and whether the corresponding zone has a low voltage (less than 1 kV). The example routine 64 is suitably configured for the example zone 42, which can include a panelboard or switchgear, and which can employ a low voltage or medium voltage.

Referring to FIG. 4C, the example routine 66 determines the normalized incident energy (Eₙ) at 74 employing Equation 2 based upon the type of enclosure, whether the corresponding zone is a grounded or an ungrounded system, and whether the corresponding zone includes switchgear or a panelboard.

FIG. 4D shows the example routine 68 to determine the final incident energy (E) at 76 employing Equation 3 based upon whether the system is low voltage, whether there is switchgear or a panelboard, and the arcing time for a circuit breaker (with ZSI and ARMS both being disabled), ZSI being enabled, or ARMS being enabled. The final incident energy (E) is displayed at 77. Communication of ZSI or ARMS being enabled is discussed, below, in connection with FIG. 11. This example employs standard values for distance for switchgear, panelboards and for low or medium voltage applications. Alternatively, those distances could be dynamic as input from a personnel distance sensor or range finder 78 (FIG. 9), if available, or else can default to the standard distance, as shown. The arcing interruption time is selected from the group consisting of: (1) tₘₐₓ which is a maximum fault interruption time for the circuit interrupter, (2) t_{ZSI} which less than tₘₐₓ whenever ZSI is enabled for the corresponding power circuit zone, and (3) t_{ARMS} which is less than t_{ZSI} whenever ARMS is enabled for the corresponding power circuit zone.

Another variable factor is system voltage. High line voltage, sagging line voltage, and swells in the voltage can affect the incident energy potential. Instead of using standard values of line voltage, the actual voltage value is sensed by the voltage sensor 61 (FIG. 11), is used in the calculation, and is optionally displayed.

In FIGS. 4B-4D, various values of interest (e.g., I_{bf}; switchgear/panelboard; grounded/ungrounded) can be predetermined (or configured) and be stored by the example meter or display device 4 for the disclosed calculations.

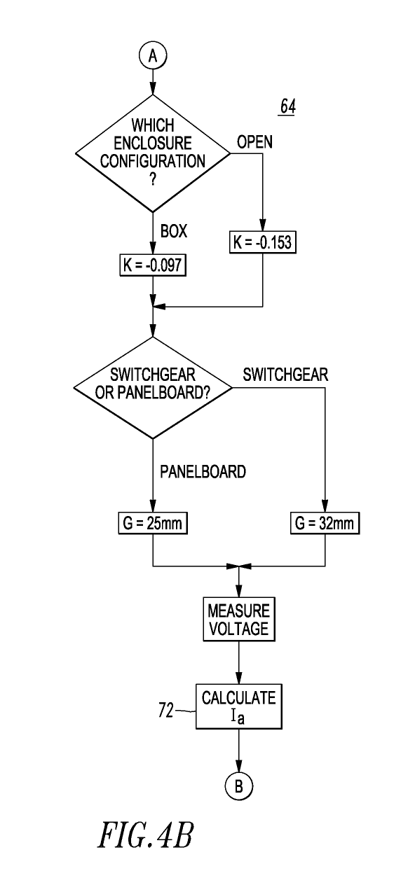

FIG. 5 shows a representation 80 of a portion of a one line diagram similar to a portion of the one line diagram 18 of FIG. 2 except showing circuit breaker 82 (CB 1.1.1.1) in an ARMS mode and a display 84 showing a relatively lower value 86 of potential incident energy for zone 54 (zone 1.1.1.1). For example, there is the ARMS protection mode that can be enabled on the circuit breaker 82. This protection mode can be a special hardware feature in the circuit breaker trip unit (not shown) or can be a lower instantaneous setting of the protective relay (not shown) or the electronic trip unit (not shown) of the circuit breaker 82. When the circuit breaker 82 is in this mode, the downstream distribution system will be at a relatively lower value of incident energy potential.

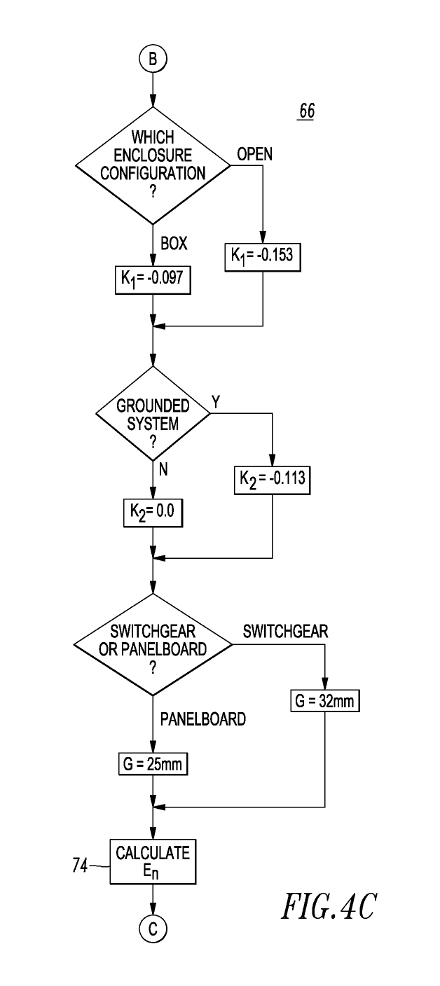

Referring to FIG. 6, a representation 92 is shown of a portion of a one line diagram similar to a portion of the one line diagram 18 of FIG. 2 except showing circuit breaker 94 (CB 2.1.1.1) that has ZSI enabled with the downstream zone 56 (zone 2.1.1.1) and the two panelboards 95,96. A display 97 shows a relatively lower value 98 of potential incident energy for the zone 56. Also, displays 99,100 show relatively lower values 101,102 of potential incident energy for the panelboards 95,96, respectively.

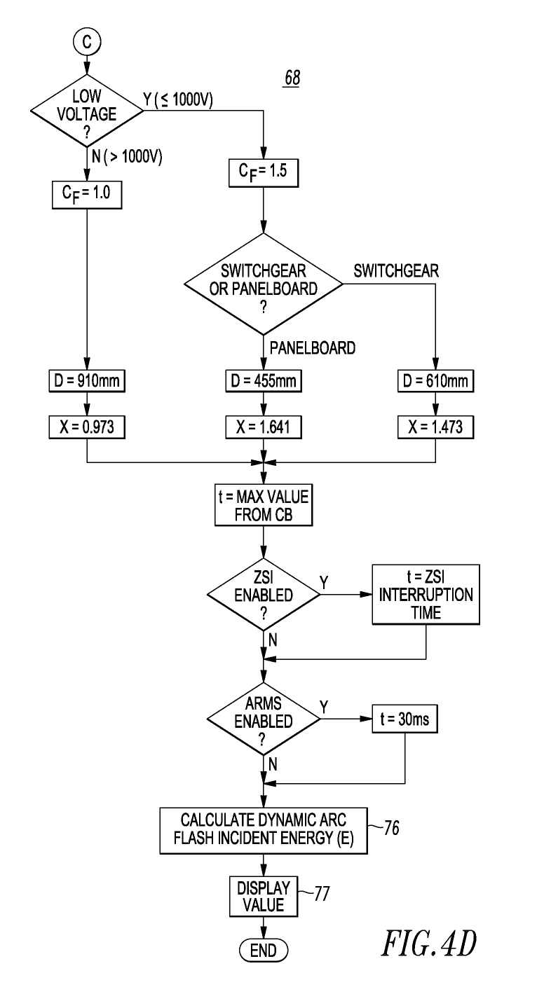

FIG. 7 shows a representation 103 of a portion of a one line diagram similar to a portion of the one line diagram 18 of FIG. 2 except showing circuit breaker 52 (CB 3.1.2) that is opened. A display 104 shows a relatively lower value 106 of potential incident energy for zone 58 (zone 3.1.2.1).

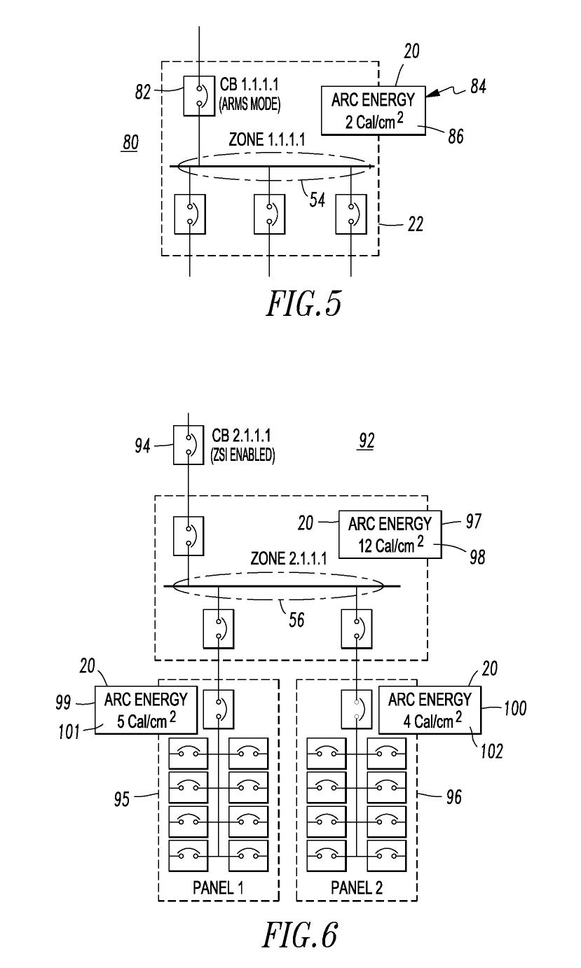

Referring to FIG. 8, a representation 112 is shown of a one line diagram similar to the one line diagram 18 of FIG. 2 except that the generator 30 (G1) is turned on and the corresponding circuit breaker 38 and tie circuit breaker 50 are closed and paralleled with the utility feeds 26,28 when the tie circuit breaker 48 is also closed. Displays 122 show relatively higher values 124 of potential arc flash incident energy throughout the electrical distribution system because of the generator 30.

For example, if generator G1 or G2 is started and if the generator is paralleled to main utility U1 or U2, then this could raise the level of incident energy. Also, if multiple generators G1,G2 are paralleled together then the level of incident energy will rise with the number of generators that are paralleled which is another dynamic feature. As another example, if utility U1 or U2 is off and the system is only running on one generator G1 or G2, then the incident energy level will decrease if the generator has a lower level of symmetrical fault current capability.

FIG. 9 shows switchgear 128 including a meter or display device 130, which can be the same as or similar to the meter or display devices 4,14 of FIGS. 1 and 2. The device 130 includes one or more of the personnel distance sensor or range finder (PDS) 78. In this example, one person (e.g., without limitation, a maintenance worker) 132 is standing very close to the switchgear 128 and another person 134 is standing some distance further away. The personnel distance sensor 78 senses the distance to the closest person 132. The device 130 includes a display 136 showing the incident energy value 138 that corresponds to the sensed distance the closest person 132 is away from the switchgear 128. The sensor 78 is located on the front of the switchgear 128 and is calibrated to a safe distance out from the switchgear. When a person walks into the location (e.g., zone) corresponding to the switchgear 128, the device 130 automatically calculates and displays a new value of the incident energy value 138 for the distance that person is away from the switchgear 128.

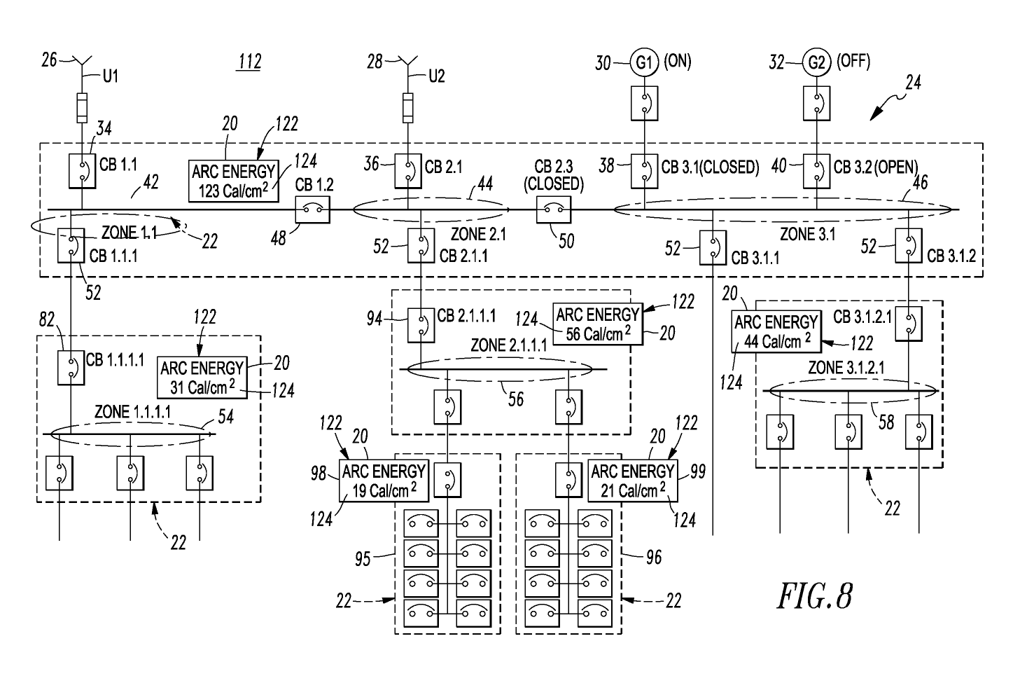

Referring to FIG. 10, if a person opens one of the switchgear doors 140 of switchgear 141 (or panelboard doors), then the person is at a much higher risk of being exposed to the incident energy should there be an arc flash incident. The status of whether the doors 140 are open or closed can be input by a meter or display device 142, which can be the same as or similar to the meter or display devices 4,14 of FIGS. 1 and 2, that performs the dynamic incident energy calculation. The device 142 is configured to know where the various doors 140 are located and where on a one line diagram (e.g., FIG. 3) to do the dynamic calculation of the potential incident energy in a corresponding location (e.g., zone).

The location of a person (e.g., 132 of FIG. 9) with respect to the switchgear doors 140 can also be an input to the meter or display device 142 using the personnel distance sensor 78 of FIG. 9. That distance will also affect the value of potential incident energy. Hence, instead of using typical values as found in the IEEE 1584 standard, the actual working distance can be used. The sensed distance (D) using a distance sensor 78 is shown in Equation 3.

The switchgear 141 includes a number of the door sensors (DS) 60 for the number of doors 140. Using Equation 1 or the routine 64 of FIG. 4B, the meter or display device 142 can calculate different values of the potential incident energy based upon the corresponding door 140 being open or closed. The switchgear doors 140 are monitored and that information is input by the meter or display device 142. For example, when door 140A is opened, this door has an empty cell behind it and there is no change to the calculated and displayed incident energy value 143. For example and without limitation, if door 140B is opened, then the calculated incident energy value goes into effect. A warning alarm is displayed (e.g., without limitation, displayed energy values are in red) or the display will flash the energy value.

FIG. 11 shows a block diagram of the meter or display device 4 of FIG. 1, which is for one or more power circuit zones, such as 42,44,46 of FIG. 3. The device 4 includes a processor 144 having a plurality of dynamic inputs 146, the routines 62,64,66,68 of FIGS. 4A-4D, and an output 148. The routines 62,64,66,68 input the dynamic inputs 146, calculate the incident energy (at 76 of FIG. 4D) of one of the power circuit zones, and output (at 77 of FIG. 4D) the output 148. The display 6 displays at least the calculated incident energy from the processor output 148.

The dynamic inputs 146 include one or more of: (1) a communication input 150 that inputs whether a utility power source (e.g., U1 or U2 of FIG. 3) is unavailable and a number of generators (e.g., G1 or G2 of FIG. 3) are available (e.g., a generator is started and a corresponding circuit breaker, such as 38 or 40 of FIG. 3, is closed); (2) the communication input 150 that inputs whether a plurality of different power sources (e.g., U1,U2,G1,G2 of FIG. 3) are available (e.g., a corresponding circuit breaker, such as 34 or 36 of FIG. 3, is closed); (3) the communication input 150 that inputs a protection mode of a circuit interrupter, a trip unit or a protective relay of a power circuit zone (e.g., circuit breaker 82 for zone 54 (zone 1.1.1.1); (4) the communication input 150 that inputs whether a generator (e.g., G1,G2 of FIG. 3) is started and paralleled to a utility power source (e.g., U1,U2 of FIG. 3 based upon the state of the circuit breakers 34,36,38,40,48,50); (5) the communication input 150 that inputs whether a plurality of generators (e.g., G1,G2 of FIG. 3) are started and paralleled together (based upon the state of the circuit breakers 38,40,50 of FIG. 3); (6) the communication input 150 that inputs whether a ZSI system is enabled of a circuit interrupter, a trip unit or a protective relay (e.g., circuit breaker 82 of FIG. 3) of a corresponding power circuit zone; (7) the door sensor 60 that senses an open door 140 (FIG. 10) of the example switchgear 141 of a corresponding power circuit zone; (8) the voltage sensor 61 that senses a system voltage of a corresponding power circuit zone; and (9) the distance sensor 78 that senses a distance between a person and the example switchgear 128 of a corresponding power circuit zone.

The example communication input 150 can be, for example and without limitation, a network communication controller that, for example and without limitation, interconnects the processor 144 with one or more of the circuit breakers, such as 34,36,38,48,50,52 of FIG. 3, or with other suitable interfaces to the power sources 26,28,30,32 of FIG. 3, using a suitable communication bus or communication network (not shown). For example, the network communication controller can poll or query whether ZSI or ARMS is enabled, or whether a particular circuit breaker is open or closed.

The disclosed meter or display devices 2,14,130,142 calculate actual real time arc flash incident energy values based upon plural dynamic inputs and display a number of dynamic values or a one line diagram that shows locations (e.g., zones) that are affected by changes in the dynamic inputs. These devices dynamically calculate and display the present value of the arc flash incident energy. A static value may not be the right value at any one instant in time and there are many factors in the incident energy value that change when electrical distribution system parameters change.

While for clarity of disclosure reference has been made herein to the example displays, such as 6 or 16, for displaying the example dynamic value 8 and/or the example one line diagram 18, it will be appreciated that such information may be stored, be printed on hard copy, be computer modified, or be combined with other data. All such processing shall be deemed to fall within the terms “display” or “displaying” as employed herein.

While specific embodiments of the disclosed concept have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the disclosed concept which is to be given the full breadth of the claims appended and any and all equivalents thereof.

What is claimed is:

1. A meter or display device for at least one power circuit zone, said device comprising:
a processor including a plurality of dynamic inputs, a routine and an output, the routine being structured to input the dynamic inputs, calculate incident energy of one power circuit zone of the at least one power circuit zone, and output said output; and
a display structured to display at least the calculated incident energy from the output of said processor.

2. The meter or display device of claim 1 wherein one of said dynamic inputs includes a distance sensor that senses a distance between a person and switchgear or a panelboard of said one power circuit zone of the at least one power circuit zone.

3. The meter or display device of claim 1 wherein said display is further structured to display a dynamic value representing the calculated incident energy.

4. The meter or display device of claim 3 wherein said display is further structured to display a one line diagram including a representation of the at least one power circuit zone and the dynamic value.

5. The meter or display device of claim 1 wherein one of said dynamic inputs includes a communication input that inputs a protection mode of a circuit interrupter, a trip unit or a protective relay of the at least one power circuit zone.

6. The meter or display device of claim 5 wherein the protection mode is an Arc Reduction Maintenance System mode.

7. The meter or display device of claim 1 wherein one of said dynamic inputs includes a communication input that inputs whether a Zone Selective Interlocking system is enabled of a circuit interrupter, a trip unit or a protective relay of the at least one power circuit zone.

8. The meter or display device of claim 1 wherein one of said dynamic inputs includes a communication input that inputs whether a generator is started and paralleled to a utility power source.

9. The meter or display device of claim 1 wherein one of said dynamic inputs includes a communication input that inputs whether a plurality of generators are started and paralleled together.

10. The meter or display device of claim 1 wherein one of said dynamic inputs includes a communication input that inputs whether a utility power source is unavailable and a number of generators are available.

11. The meter or display device of claim 1 wherein one of said dynamic inputs includes a door sensor that senses an open door of switchgear or a panelboard of said one power circuit zone of the at least one power circuit zone.

12. The meter or display device of claim 1 wherein one of said dynamic inputs includes a voltage sensor that senses a system voltage of said one power circuit zone of the at least one power circuit zone.

13. The meter or display device of claim 1 wherein said routine is configured for said one power circuit zone of the at least one power circuit zone including a panelboard or switchgear, and for said one power circuit zone of the at least one power circuit zone being low voltage or medium voltage.

14. The meter or display device of claim 1 wherein said routine is configured for at least one of:
a predetermined bolted fault current from each of a plurality of different power sources that power said one power circuit zone of the at least one power circuit zone,
whether said one power circuit zone of the at least one power circuit zone is switchgear or a panelboard, and
whether said one power circuit zone of the at least one power circuit zone is grounded or ungrounded.

15. The meter or display device of claim 1 wherein a plurality of said dynamic inputs include a communication input that inputs whether a plurality of different power sources are available; and wherein said routine is further structured to calculate the bolted fault current for said different power sources that are available.

16. The meter or display device of claim 1 wherein said routine is further structured to calculate arcing current (Iₐ) from:
log Iₐ=K+0.662 log I_{bf}+0.0966V+0.000526G+0.5588V log I_{bf}−0.00304G log I_{bf}
wherein:
Iₐ is said calculated arcing current;
K is −0.153 for an open enclosure configuration, or is −0.097 for a box configuration;
I_{bf} is bolted fault current;
V is system voltage of said one power circuit zone of the at least one power circuit zone; and
G is a gap between conductors of said switchgear or said panelboard.

17. The meter or display device of claim 16 wherein said routine is further structured to calculate normalized incident energy (Eₙ) from:
log Eₙ=K₁+K₂+1.081 log Iₐ+0.0011G
wherein:
K₁ is −0.792 for the open enclosure configuration, or is −0.555 for the box configuration; and
K₂ is 0 for the switchgear or the panelboard being an ungrounded or high resistance grounded system, or is −0.113 for the switchgear or the panelboard being a grounded system.

18. The meter or display device of claim 17 wherein said routine is further structured to calculate final incident energy (E) from:
E=4.184C_{f}Eₙ(t/0.2)(610^{X}/D^{X})
wherein:
C_{f} is 1.0 for the system voltage being above 1 kV, or is 1.5 for the system voltage being below 1 kV;
X is a distance exponent, which is a function of type of switchgear and system voltage;
t is arcing interruption time of a circuit interrupter feeding said one power circuit zone of the at least one power circuit zone; and
D is a sensed or a predetermined distance from a possible arcing point in said one power circuit zone of the at least one power circuit zone to a person.

19. The meter or display device of claim 18 wherein said arcing interruption time is selected from the group consisting of:
tₘₐₓ which is a maximum fault interruption time of a circuit interrupter for said one power circuit zone of the at least one power circuit zone,
t_{ZSI} which less than tₘₐₓ whenever Zone Selective Interlocking is enabled for said one power circuit zone of the at least one power circuit zone, and
t_{ARMS} which is less than t_{ZSI} whenever an Arc Reduction Maintenance System is enabled for said one power circuit zone of the at least one power circuit zone.

20. The meter or display device of claim 11 wherein said routine is further structured to calculate arcing current for said one power circuit zone of the at least one power circuit zone as a function of whether there is an open enclosure configuration or a box configuration, whether said one power circuit zone of the at least one power circuit zone includes the switchgear or the panelboard, and whether said one power circuit zone of the at least one power circuit zone includes a low voltage.

21. The meter or display device of claim 20 wherein said routine is further structured to calculate normalized incident energy for said one power circuit zone of the at least one power circuit zone as a function of the calculated arcing current, whether there is the open enclosure configuration or the box configuration, whether said one power circuit zone of the at least one power circuit zone is a grounded system, and whether there is the switchgear or the panelboard.

22. The meter or display device of claim 21 wherein said routine is further structured to calculate final incident energy for said one power circuit zone of the at least one power circuit zone as a function of the calculated normalized incident energy, whether said one power circuit zone of the at least one power circuit zone includes the low voltage, whether there is the switchgear or the panelboard, and arcing interruption time of a circuit interrupter feeding said one power circuit zone of the at least one power circuit zone.

23. The meter or display device of claim 1 wherein:
one of said dynamic inputs includes a distance sensor that measures a distance between a person and switchgear or a panelboard of said one power circuit zone of the at least one power circuit zone, or
said routine is configured for a standard value of distance between a person and switchgear or a panelboard of said one power circuit zone of the at least one power circuit zone.

24. The meter or display device of claim 4 wherein said at least one power circuit zone is a plurality of different power circuit zones; and wherein said display is further structured to display a plurality of dynamic values each of which represents a calculated incident energy for a corresponding one of the different power circuit zones.
